(19) United States
(12) Patent Application Publication
(10) Pub. No.: US 2024/0006291 A1
(43) Pub. Date: Jan. 4, 2024

(54) POCKETED COPPER IN FIRST LAYER INTERCONNECT AND METHOD

(71) Applicant: Intel Corporation, Santa Clara, CA (US)

(72) Inventors: Suddhasattwa Nad, Chandler, AZ (US); Jeremy D. Ecton, Gilbert, AZ (US); Brandon C. Marin, Gilbert, AZ (US); Srinivas Venkata Ramanuja Pietambaram, Chandler, AZ (US); Gang Duan, Chandler, AZ (US); Jason Steill, Phoenix, AZ (US); Yi Yang, Gilbert, AZ (US); Marcel Arlan Wall, Phoenix, AZ (US)

(21) Appl. No.: 17/855,961

(22) Filed: Jul. 1, 2022

(51) Int. Cl. H01L 23/498; H01L 21/48

(52) U.S. Cl. CPC H01L 23/49838; H01L 21/481; H01L 21/4853; H01L 23/49894; H01L 23/49816

(57) ABSTRACT

A substrate package comprises a substrate comprised of buildup layers. The substrate package can further include a passivating layer connected to the substrate and including a pocketed region. The pocketed region can include a first portion thinner than a second portion extending from the first portion. The substrate package can further include a solder ball encapsulated within the pocketed region. Other systems, apparatuses and methods are described.

### TECHNICAL FIELD

Embodiments pertain to semiconductor devices and packaging.

### BACKGROUND

Integrated circuits (ICs) and other electronic components or devices can be packaged on a semiconductor package. Smaller scaling of integrated circuits has allowed a larger number of small features and increased densities of functional components on such semiconductor packages. Some IC packages can enable high speed input/output (HSIO) and make use of fine line features on the metal layers immediately below the solder resist surface. As such smooth copper may be included on this metal layer while integrating with the first layer interconnect surface finish.

### BRIEF DESCRIPTION OF THE DRAWINGS

FIG. 1 is an illustration of a substrate package with a solder resist layer;

FIGS. 2A-2H show intermediate steps of a method of manufacture of a package that includes pocket regions in accordance with some embodiments; and

FIG. 3 shows a flow diagram of a method of manufacture of a package that includes pocket regions in accordance with some example embodiments; and

FIG. 4 illustrates a system level diagram in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

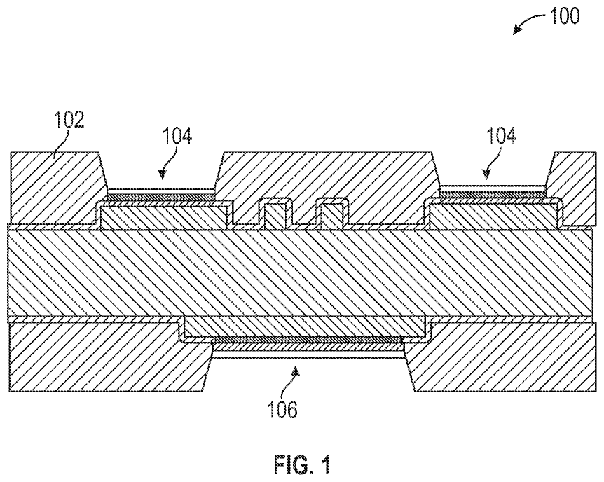

Electronic systems often include integrated circuits (ICs) that are attached to substrate materials and packaged as a semiconductor package. FIG. 1 is an illustration of a substrate package 100 with a solder resist layer 102 that can be used in available systems as well as in some embodiments of the disclosure.

Solder resist layer 102 can resist solder application at the points where the solder resist layer 102 is present. Solder resist layer 102 can comprise a thin layer of polymer that is applied to protect copper or other metal surfaces of the substrate package 100 from oxidation and to prevent bridges from forming between closely spaced solder pads. Openings 104 can be provided for solder ball attachment (not shown in FIG. 1), to other circuits or ICs. Openings 106 can be larger than openings 104 (though embodiments are not limited thereto) for solder ball attachment to the motherboard, etc.

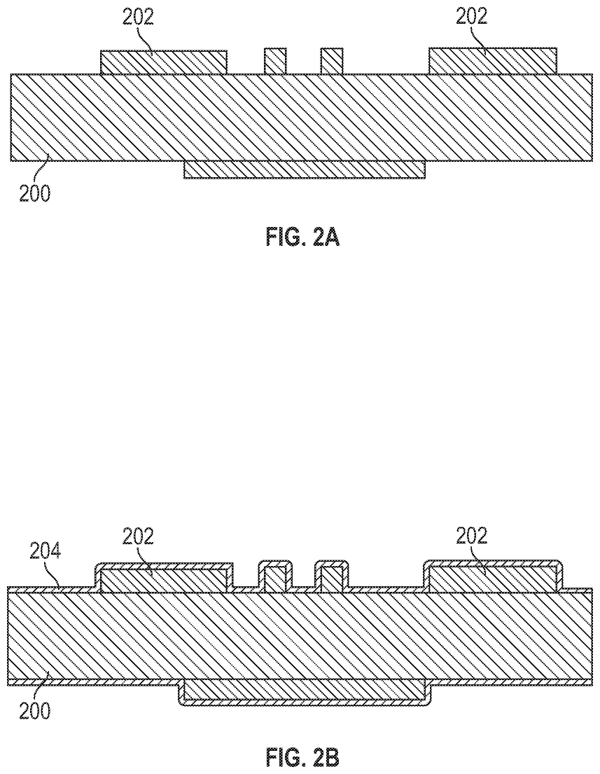

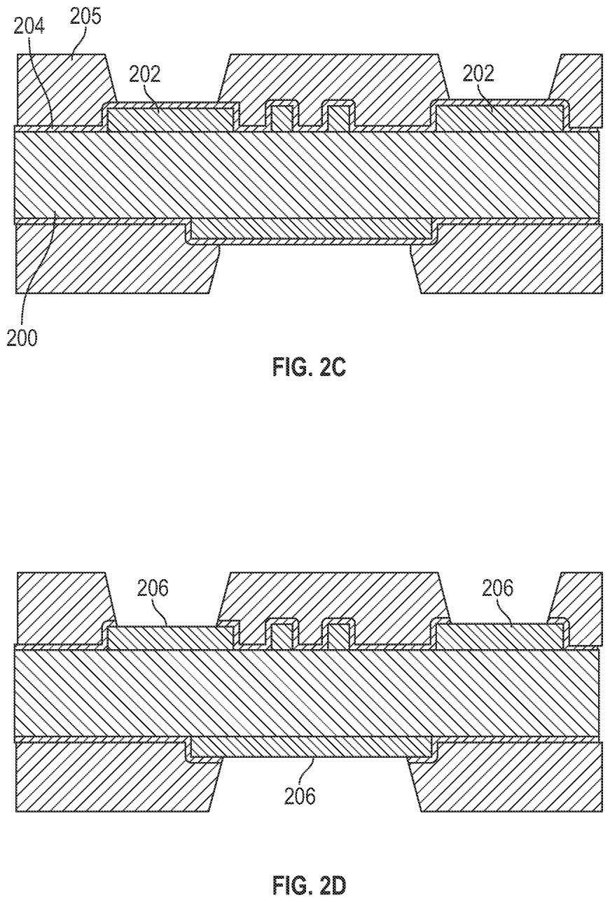

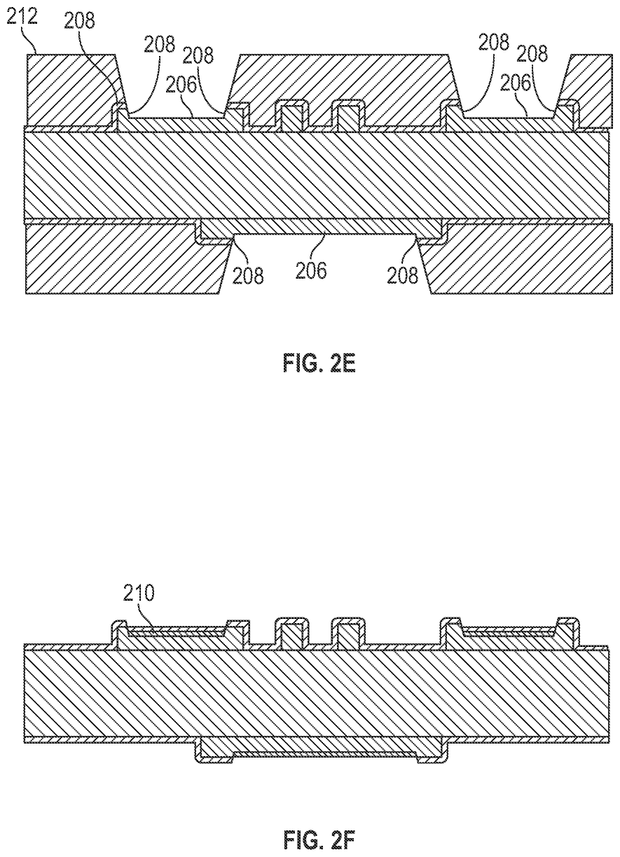

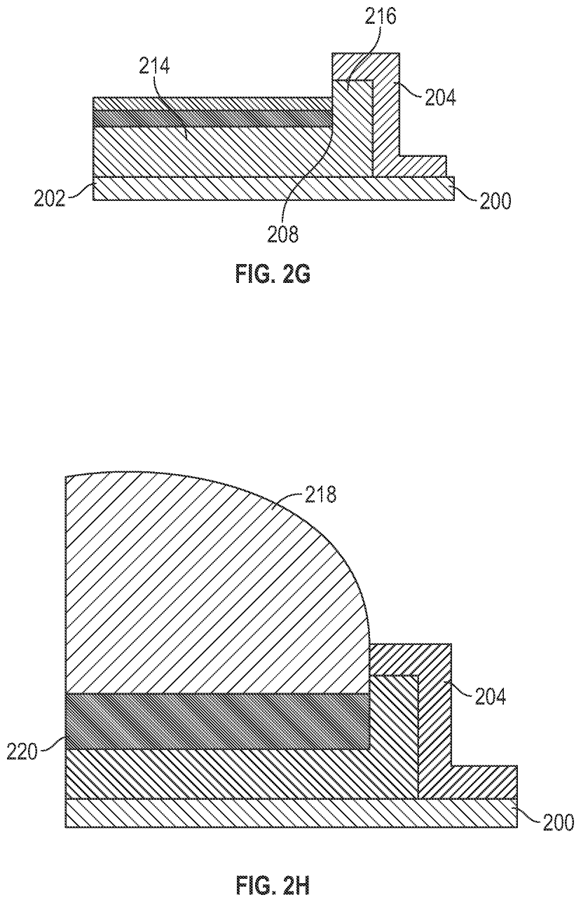

As package sizes become smaller, however, it may be desirable to provide solder ball attachment without use of the solder resist layer 102. However, if the solder resist layer 102 is not present, then openings 104 are not available for solder ball placement. Therefore, methods and substrate packages according to embodiments provide a pocketed region within passivity layers. Solder ball attachment can then be made within that pocketed region, e.g., the solder ball can be encapsulated within the pocketed region. FIGS. 2A-2H show intermediate steps of a method of manufacture of a substrate package that includes pocketed regions in accordance with some embodiments.

In FIG. 2A, a core 200 and buildup layers 202 are provided. The build up layers 202 can be comprised of conductive material sandwiched between layers of dielectric material. The conductive material can include, for example, copper although embodiments are not limited thereto. The core 200 can include redistribution layers (RDLs) not separately shown in the figure that can provide connections, vias, and other structures.

In FIG. 2B, a SiNx film 204 is applied to the final metal layer of the build up layers 202 before dry film photoresist (DFR) patterning 205 of FIG. 2C, such that the SiNx film 204 mimics the build-up layers 202 and acts as, for example, a passivating layer. The SiNx film 204 can be provided in the place of solder resist layers 102 (FIG. 1). The film 204 can also be comprised of silicon oxynitrides, silicon oxide, photoimageable dielectrics (PID), other nitrogen-based substances, etc.

In FIG. 2D, dry desmear can then be used to remove the SiNx in the exposed areas. In a conventional solder resist-enabled flow, these now exposed pads 206 are solder resist openings (SROs). In FIG. 2E, the copper pads 206 are then etched to create pocketed regions 208. In FIG. 2F, surface finish 210 can then be applied before the DFR 212 is stripped off. The surface finish 210 can be comprised of, for example, Surface finishes such as electroless nickel/electroless palladium/immersion gold (ENEPIG), electroless nickel/immersion gold (ENIG), organic solderability preservative (OSP), etc. The operation of FIG. 2F reveals a substrate with surface finished pads 214 where the final metal layer, which may have copper traces on the same layer, are protected by a SiNx film.

FIG. 2G illustrates further details of pocketed region 208. The pocketed regions 208 can be understood as including a first portion that has been etched into copper or other metal as described with reference to FIG. 2E and is therefore thinner than surrounding portions, for example second portion 216. The second portion 216 is shown as extending from the first portion, while the first and second portion 216 are comprised of the same material, e.g., copper or other metal. The second portion 216 can extend at any angle that could allow for encapsulating of the solder ball within the juncture between the second portion 216 and the first portion, or at an any angle with other considerations. The pocketed region 208 formed thereby can be shaped such that solder ball 218 can be attached as shown in FIG. 2H. The solder ball 218 attach process can be enabled by using a pad etch process, for example. An intermetallic region 220 can be included between the solder ball 218 and the copper pad.

According to the above process, embodiments can make the solder resist layer 102 redundant with a passivity layer application, thereby removing the necessity of providing a solder resist layer 102 and allowing for thinner (e.g., smaller Z-dimension height) substrate packages. The passivity layer can include, for example, silicon nitride (SiNx) although embodiments are not limited thereto. SiNx films can provide a smooth copper interface for surface routed high speed input/output (HSIO) traces, in addition to providing protection for any copper or other metal components or traces. Solder resist layers 102 can thus be eliminated resulting in a cheaper, thinner and more capable substrate package.

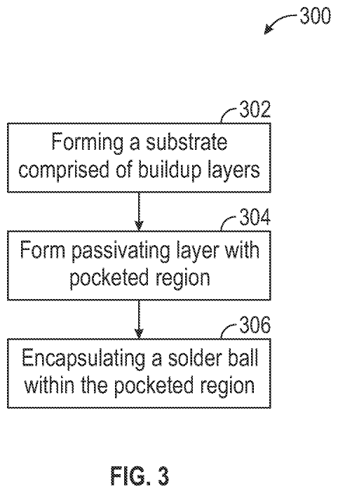

FIG. 3 shows a flow diagram of a method 300 of manufacture of a package that includes pocketed regions in accordance with some example embodiments. The method 300 can begin with operation 302 with forming a substrate core 200 (FIG. 2A) comprised of buildup layers. The method 300 can continue with operation 304 with forming a passivating layer comprised of, for example, SiNx film 204 (FIG. 2B) connected to the substrate and including a pocketed region 208. The pocketed region 208 can include a first portion thinner than a second portion 216 extending from the first portion. The method 300 can include operation 306 by encapsulating a solder ball within the pocketed region. In some embodiments, further comprising forming the pocketed region by etching an area into a copper pad (see e.g., FIG. 2E).

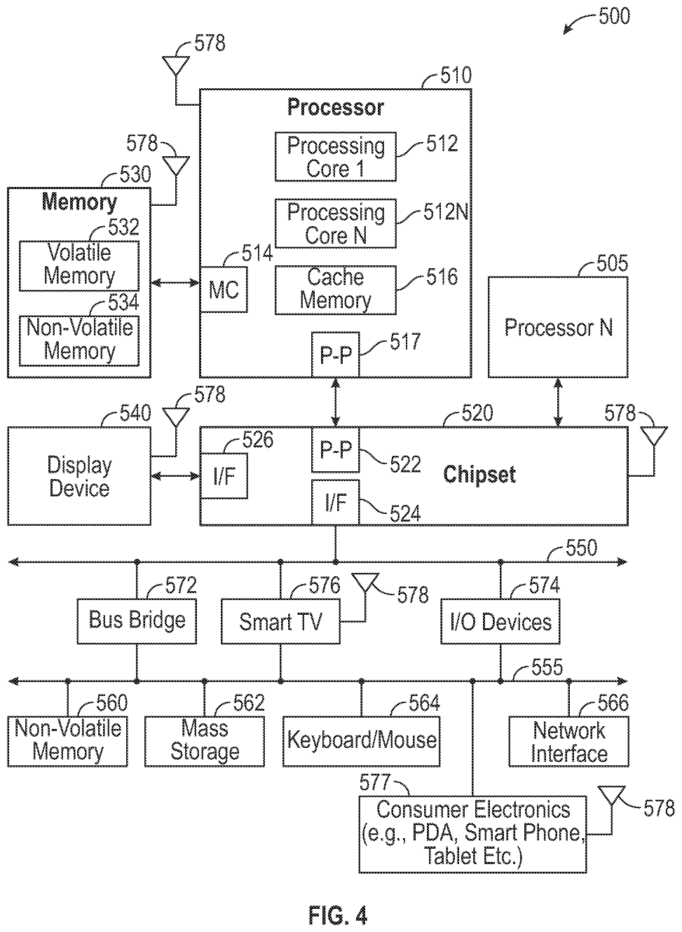

FIG. 4 illustrates a system level diagram, according to one embodiment of the invention. For instance, FIG. 4 depicts an example of a system that can include an electronic device in which a substrate is included that has a SiNx film in place of a solder resist layer to provide a smooth copper interface for surface routed HSIOs. In one embodiment, system 500 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance, or any other type of computing device. In some embodiments, system 500 is a system on a chip (SOC) system. In some embodiments, some components can be included in vehicular systems (e.g., automotive, avionics, etc.). The device can include one or more semiconductor dies, which can include microprocessors, SoCs, etc.

In one embodiment, processor 510 has one or more processing cores 512 and 512N, where N is a positive integer and 512N represents the Nth processor core inside processor 510. In one embodiment, system 500 includes multiple processors including 510 and 505, where processor 505 has logic similar or identical to the logic of processor 510. In some embodiments, processing core 512 includes, but is not limited to, pre-fetch logic to fetch instructions, decode logic to decode the instructions, execution logic to execute instructions and the like. In some embodiments, processor 510 has a cache memory 516 to cache instructions and/or data for system 500. Cache memory 516 may be organized into a hierarchal structure including one or more levels of cache memory.

In some embodiments, processor 510 includes a memory controller 514, which is operable to perform functions that enable the processor 510 to access and communicate with memory 530 that includes a volatile memory 532 and/or a non-volatile memory 534. In some embodiments, processor 510 is coupled with memory 530 and chipset 520. Processor 510 may also be coupled to a wireless antenna 578 to communicate with any device configured to transmit and/or receive wireless signals. In one embodiment, the wireless antenna interface 578 operates in accordance with, but is not limited to, the IEEE 802.11 standard and its related family, Home Plug AV (HPAV), Ultra-Wide Band (UWB), Bluetooth, WiMax, or any form of wireless communication protocol.

In some embodiments, volatile memory 532 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 534 includes, but is not limited to, flash memory, phase change memory (PCM), read-only memory (ROM), electrically erasable programmable read-only memory (EEPROM), or any other type of non-volatile memory device.

Memory 530 stores information and instructions to be executed by processor 510. In one embodiment, memory 530 may also store temporary variables or other intermediate information while processor 510 is executing instructions. In the illustrated embodiment, chipset 520 connects with processor 510 via Point-to-Point (PtP or P-P) interfaces 517 and 522. Chipset 520 enables processor 510 to connect to other elements in system 500. In some embodiments of the invention, interfaces 517 and 522 operate in accordance with a PtP communication protocol such as the Intel® QuickPath Interconnect (QPI) or the like. In other embodiments, a different interconnect may be used.

In some embodiments, chipset 520 is operable to communicate with processor 510, 505N, display device 540, and other devices 572, 576, 574, 560, 562, 564, 566, 577, etc. Buses 550 and 555 may be interconnected together via a bus bridge 572. Chipset 520 connects to one or more buses 550 and 555 that interconnect various elements 574, 560, 562, 564, and 566. Chipset 520 may also be coupled to a wireless antenna 578 to communicate with any device configured to transmit and/or receive wireless signals. Chipset 520 connects to display device 540 via interface (I/F) 526. Display 540 may be, for example, a touchscreen, a liquid crystal display (LCD), a plasma display, cathode ray tube (CRT) display, or any other form of visual display device. In some embodiments of the invention, processor 510 and chipset 520 are merged into a single SOC. In one embodiment, chipset 520 couples with (e.g., via interface 524) a non-volatile memory 560, a mass storage medium 562, a keyboard/mouse 564, and a network interface 566 via OF 524 and/or OF 526, I/O devices 574, smart TV 576, consumer electronics 577 (e.g., PDA, Smart Phone, Tablet, etc.).

In one embodiment, mass storage medium 562 includes, but is not limited to, a solid state drive, a hard disk drive, a universal serial bus flash memory drive, or any other form of computer data storage medium. In one embodiment, network interface 566 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra-Wide Band (UWB), Bluetooth, WiMax, or any form of wireless communication protocol.

While the modules shown in FIG. 4 are depicted as separate blocks within the system 500, the functions performed by some of these blocks may be integrated within a single semiconductor circuit or may be implemented using two or more separate integrated circuits. For example, although cache memory 516 is depicted as a separate block within processor 510, cache memory 516 (or selected aspects of 516) can be incorporated into processor core 512.

The devices, systems, and methods described can provide improved thermal conductivity in electronic device packages. Examples described herein include one SoC for simplicity, but one skilled in the art would recognize upon reading this description that the examples can include more than one SoC system.

### ADDITIONAL DESCRIPTION AND EXAMPLES

Example 1 is a substrate package comprising a substrate comprised of buildup layers; a passivating layer connected to the substrate and including a pocketed region, the pocketed region including a first portion thinner than a second portion extending from the first portion; and a solder ball encapsulated within the pocketed region.

In Example 2, the subject matter of Example 1 can include wherein the substrate package does not include a solder resist layer.

In Example 3, the subject matter of any of Examples 1-2 can include wherein the solder ball is attached into a pocketed pad within the pocketed region.

In Example 4, the subject matter of Example 3 can include wherein the pocketed pad comprises copper.

In Example 5, the subject matter of Example 3 can include wherein an intermetallic layer is provided between the solder ball and the pocketed pad.

In Example 6, the subject matter of any of Examples 1-5 can include wherein the passivating layer is comprised of a silicon nitride (SiNx) film.

In Example 7, the subject matter of any of Examples 1-6 can include wherein the pocketed region includes a surface finish layer.

In Example 8, the subject matter of Example 7 can include wherein the surface finish layer comprises at least one of electroless nickel/electroless palladium/immersion gold (ENEPIG), electroless nickel immersion gold (ENIG), or organic solderability preservative (OSP).

Example 9 is an electronic device comprising a substrate package comprising: a substrate comprised of buildup layers; a passivating layer connected to the substrate and including a pocketed region, the pocketed region including a first portion thinner than a second portion extending from the first portion; a solder ball encapsulated within the pocketed region; and an integrated circuit mounted to the substrate package.

In Example 10, the subject matter of Example 9 can include wherein the substrate package includes surface routed high speed input/output (HSIO) comprised of copper traces.

In Example 11, the subject matter of any of Examples 9-10 can include wherein the substrate package does not include a solder resist layer.

In Example 12, the subject matter of any of Examples 9-11 can include wherein the solder ball is attached into a pocketed pad within the pocketed region.

In Example 13, the subject matter of Example 12 can include wherein the pocketed pad comprises copper.

In Example 14, the subject matter of Example 12 can include wherein an intermetallic layer is provided between the solder ball and the pocketed pad.

In Example 15, the subject matter of any of Examples 9-14 can include wherein the passivating layer is comprised of a silicon nitride (SiNx) film.

In Example 16, the subject matter of any of Examples 9-15 can include wherein the pocketed region includes a surface finish layer.

Example 17 is a method of manufacture of a substrate package, the method comprising: forming a substrate comprised of buildup layers; forming a passivating layer connected to the substrate and including a pocketed region, the pocketed region including a first portion thinner than a second portion extending from the first portion; and encapsulating a solder ball within the pocketed region.

In Example 18, the subject matter of Example 17 can include forming the pocketed region by etching an area into a copper pad.

In Example 19, the subject matter of Example 18 can include attaching the solder ball to a pocketed pad within the pocketed region.

In Example 20, the subject matter of any of Examples 17-19 can include wherein the passivating layer is comprised of a silicon nitride (SiNx) film and whereon the method further comprising providing a surface finish layer over the pocketed region, the surface finish layer comprising at least one of electroless nickel/electroless palladium/immersion gold (ENEPIG), electroless nickel immersion gold (ENIG), or organic solderability preservative (OSP).

These non-limiting examples can be combined in any permutation or combination. The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. A substrate package comprising:
a substrate comprised of buildup layers;
a layer connected to the substrate and including a pocketed region, the layer including silicon and nitrogen, the pocketed region including a first portion thinner than a second portion extending from the first portion; and
a solder ball encapsulated within the pocketed region.

2. The substrate package of claim 1, wherein the substrate package does not include a solder resist layer.

3. The substrate package of claim 1, wherein the solder ball is attached into a pocketed pad within the pocketed region.

4. The substrate package of claim 3, wherein the pocketed pad comprises copper.

5. The substrate package of claim 3, wherein an intermetallic layer is provided between the solder ball and the pocketed pad.

6. The substrate package of claim 1, wherein the layer comprises silicon nitride (SiNx).

7. The substrate package of claim 1, wherein the pocketed region includes a surface finish layer.

8. The substrate package of claim 7, wherein the surface finish layer comprises at least one of electroless nickel/electroless palladium/immersion gold (ENEPIG), electroless nickel immersion gold (ENIG), or organic solderability preservative (OSP).

9. An electronic device comprising:
a substrate package comprising:
a substrate comprised of buildup layers;
a passivating layer connected to the substrate and including a pocketed region, the pocketed region including a first portion thinner than a second portion extending from the first portion;
a solder ball encapsulated within the pocketed region; and
an integrated circuit mounted to the substrate package.

10. The electronic device of claim 9, wherein the substrate package includes surface routed high speed input/output (HSIO) comprised of copper traces.

11. The electronic device of claim 9, wherein the substrate package does not include a solder resist layer.

12. The electronic device of claim 9, wherein the solder ball is attached into a pocketed pad within the pocketed region.

13. The electronic device of claim 12, wherein the pocketed pad comprises copper.

14. The electronic device of claim 12, wherein an intermetallic layer is provided between the solder ball and the pocketed pad.

15. The electronic device of claim 9, wherein the passivating layer is comprised of a silicon nitride (SiNx) film.

16. The electronic device of claim 9, wherein the pocketed region includes a surface finish layer.

17. A method of manufacture of a substrate package, the method comprising:
forming a substrate comprised of buildup layers;
forming a passivating layer connected to the substrate and including a pocketed region, the pocketed region including a first portion thinner than a second portion extending from the first portion; and
encapsulating a solder ball within the pocketed region.

18. The method of claim 17, further comprising forming the pocketed region by etching an area into a copper pad.

19. The method of claim 18, further comprising attaching the solder ball to a pocketed pad within the pocketed region.

20. The method of claim 17, wherein the passivating layer is comprised of a silicon nitride (SiNx) film and whereon the method further comprising providing a surface finish layer over the pocketed region, the surface finish layer comprising at least one of electroless nickel/electroless palladium/immersion gold (ENEPIG), electroless nickel immersion gold (ENIG), or organic solderability preservative (OSP).
